(19) United States
(12) Patent Application Publication
(10) Pub. No.: US 2011/0128079 A1
(43) Pub. Date: Jun. 2, 2011

(54) MULTI-BAND POWER AMPLIFIER WITH HIGH-FREQUENCY TRANSFORMER

(75) Inventors: Taek-Jin HWANG, Daejeon (KR); Kwang-Chun LEE, Daejeon (KR)

(73) Assignee: ELECTRONICS AND TELECOMMUNICATIONS RESEARCH INSTITUTE, Daejeon (KR)

(21) Appl. No.: 12/955,797

(22) Filed: Nov. 29, 2010

(30) Foreign Application Priority Data
Nov. 30, 2009 (KR) 10-2009-0117417

(51) Int. Cl. H03F 3/68; H03F 1/22

(52) U.S. Cl. 330/295

(57) ABSTRACT

A multi-band power amplifier in a wireless communication system includes: a plurality of matching circuits connected in parallel to an output stage of the power amplifier and corresponding to a plurality of different operation frequencies, respectively; and a plurality of high-frequency amplifiers connected to the plurality of matching circuits, respectively. The plurality of high-frequency amplifiers are selectively operated depending on the operation frequencies. Each of the high-frequency amplifiers may include a plurality of stages. Each of the matching circuits may include a high-frequency transformer.

### CROSS-REFERENCE(S) TO RELATED APPLICATIONS

The present application claims priority of Korean Patent Application No. 10-2009-0117417, filed on Nov. 30, 2009, which is incorporated herein by reference in its entirety.

### BACKGROUND OF THE INVENTION

1. Field of the Invention

Exemplary embodiments of the present invention relate to a high-frequency amplifier which is used in a wireless communication system; and, more particularly, to a multi-band power amplifier with a high-frequency transformer, which may be used in a plurality of frequency bands.

2. Description of Related Art

In general, when a relatively high frequency (hereafter, referred to as a high frequency) used in a wireless communication system is received, a high-frequency amplifier is used. The high-frequency amplifier amplifies a high-frequency voltage received in a previous stage of a receiver to increase sensitivity, a signal-to-noise ratio (SNR), or selectivity. Furthermore, the high-frequency amplifier increases the stability of reception, and prevents anomalous waves from being radiated to the outside from an antenna during oscillation.

To obtain a favorable operation characteristic at a specific operation frequency, the high-frequency amplifier includes specific matching circuits which are provided in input and output stages thereof, respectively, in correspondence to the operation frequency. That is, the specific matching circuits having a favorable transfer characteristic in correspondence to the operation frequency are provided between the amplifier and the input stage including information to be amplified and between the amplifier and the output stage to output the information, respectively.

In order for one amplifier to obtain favorable operation characteristics with respect to various bands of frequencies, it is necessary to use the matching circuits which may selectively vary a transfer characteristic depending on an input frequency and have a favorable transfer characteristic in a wide frequency band.

The high-frequency amplifier capable of varying an operation frequency applies a control signal to the input and output stages by using the matching circuits capable of varying a frequency transfer characteristic. Then, an operation suitable for a desired frequency may be performed. In such a structure, inductor and capacitor elements, transmission lines, and transformers which are used in the input and output stages may be combined and configured in various possible forms. Then, a variable element or switch may be used to apply the variation of the transfer characteristic.

FIGS. 1A and 1B are circuit diagrams illustrating output-stage matching circuits of a high-frequency amplifier which is used for multi-band operations in a conventional wireless communication system. FIG. 1A illustrates a matching circuit which is optimized for a specific frequency by using a switch. FIG. 1B illustrates a matching circuit having a separate path for each frequency band.

The matching circuit using a switch, as illustrated in FIG. 1A, has the following problem. As the number of used frequency bands increases, an area for implementing the high-frequency amplifier inevitably increases, which makes it difficult to accomplish integration. Furthermore, the matching circuit having a separate path for each frequency band, as illustrated in FIG. 1B, also has a similar problem. That is, an area for implementing the high-frequency amplifier increases, which makes it difficult to accomplish integration.

To minimize a power loss caused by the switching operation, a radio frequency-micro electronic mechanical system (RF-MEMS) switch may be used. In this case, a process for manufacturing the switch is complicated. Therefore, the manufacturing costs of a matching circuit using the switch and a high-frequency amplifier may increase.

Meanwhile, a high-frequency amplifier using plural stages of matching circuits may be used to obtain a wide band of input/output frequency transfer characteristics which may be applied to a variety of operation frequencies. In this case, on-chip and off-chip elements may be used to implement a structure which may obtain a wide band of input/output frequency transfer characteristics.

In the above-described conventional frequency amplifiers, the plural stages of matching elements are integrated and arranged in the input and output stages to obtain a favorable matching characteristic. Therefore, since the size of the entire circuit increases, it is difficult to accomplish the integration. Furthermore, since the switch is used, a considerable loss may occur.

Accordingly, when a transmission stage is actually implemented, the high-frequency amplifier of FIG. 1B in which a matching circuit is configured for each frequency and an operation frequency is selected to operate only a required circuit is used in most cases.

In the high-frequency amplifier including a matching circuit implemented for each frequency, however, an amplifier for each frequency should be disposed. Therefore, the entire area of the high-frequency amplifier increases, and the utilization of the circuit configuration decreases.

### SUMMARY OF THE INVENTION

An embodiment of the present invention is directed to a multi-band power amplifier with a high-frequency transformer, which is capable of increasing the utilization of the circuit configuration without increasing the circuit size.

Another embodiment of the present invention is directed to a multi-band power amplifier with a high-frequency transformer, which is capable of performing high power and high efficiency amplification in a plurality of frequency bands, while increasing the utilization of the circuit configuration without increasing the circuit size.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

In accordance with an embodiment of the present invention, a multi-band power amplifier in a wireless communication system includes: a plurality of matching circuits connected in parallel to an output stage of the power amplifier and corresponding to a plurality of different operation frequencies, respectively; and a plurality of high-frequency amplifiers connected to the plurality of matching circuits, respectively. The plurality of high-frequency amplifiers are selectively operated depending on the operation frequencies. Each of the high-frequency amplifiers may include a plurality of stages. Each of the matching circuits may include a high-frequency transformer.

The high-frequency transformer may be matched by adjusting any one of the thickness and the length of a transmission line in correspondence to each of the operation frequencies. The high-frequency transformer may use a capacitor corresponding to each of the different operation frequencies.

The capacitor may be configured by using any one of a transistor switch and a varactor.

Each of the high-frequency amplifiers may include a common source transistor and a common gate transistor which are connected in a cascode structure.

The common source transistor and the common gate transistor may have one terminal connected to at least any one of an inductor, a resistor, a capacitor, a transmission line, an additional transistor, and a transformer.

In accordance with another embodiment of the present invention, a multi-band power amplifier in a wireless communication system includes: a plurality of high-frequency amplifiers having a cascode structure in which a plurality of common gate transistors have a source connected in parallel to a drain of one common source transistor; and a plurality of matching circuits matched with different frequency regions and connected to drains of the common gate transistors, respectively. The gates of the common gate transistors are selectively switched on/off to selectively operate the plurality of high-frequency amplifiers depending on operation frequencies.

In accordance with another embodiment of the present invention, a multi-band power amplifier with a high-frequency amplifier includes: a power amplification unit including: a plurality of common source transistors connected in parallel to a ground terminal; and a plurality of high-frequency amplifiers having a plurality of common gate transistors connected to the respective common source transistors in a cascode structure and configured to selectively amplify power of input signals each having a specific frequency; and a high-frequency transformer including: a plurality of primary-side transmission lines connected to the respective high-frequency amplifiers of the power amplification unit; and a secondary-side transmission line magnetically coupled to signals applied to the respective primary-side transmission lines. The high-frequency transformer matches the plurality of signals having different frequencies, which are applied from the power amplification unit, and outputs the signals to an output stage.

### BRIEF DESCRIPTION OF THE DRAWINGS

FIGS. 1A and 1B are circuit diagrams illustrating output-stage matching circuits of a high-frequency amplifier which is used for multi-band operations in a conventional wireless communication system.

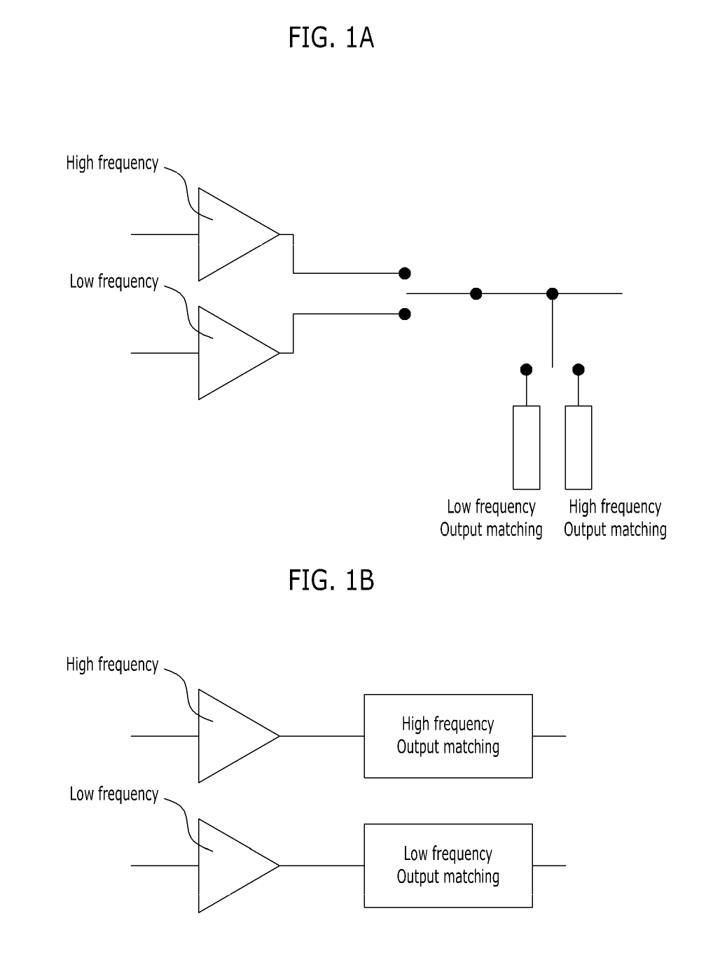

FIG. 2 is a diagram illustrating a combination form of a high-frequency amplifier and a high-frequency transformer of a multi-band power amplifier with a high-frequency transformer operating in two frequency bands, in accordance with an embodiment of the present invention.

FIG. 3 is a diagram illustrating a combination of high-frequency transformers and input signals amplified by a plurality of amplifiers in a multi-band power amplifier using a plurality of high-frequency amplifiers operating in different frequency bands in accordance with another embodiment of the present invention.

FIG. 4 is a diagram illustrating a combination form of a high-frequency amplifier and a high-frequency transformer of a multi-band power amplifier in accordance with another embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

First, the features of a multi-band power amplifier in accordance with an embodiment of the present invention will be described. In the multi-band power amplifier in accordance with the embodiment of the present invention, a plurality of matching circuits or power combining stages connected to an output stage and corresponding to different operation frequencies are connected in parallel to a plurality of transistors. The plurality of transistors are selectively operated depending on the operation frequencies.

In this embodiment, the transistors connected in parallel are implemented in a plurality of stages.

In this embodiment, a plurality of high-frequency amplifiers are formed with a differential structure.

In this embodiment, the multi-band power amplifier includes a plurality of high-frequency transformers capable of coupling power generated from the respective amplifiers.

In this embodiment, the respective transistors have a terminal connected to at least any one of an inductor, a resistor, a capacitor, a transmission line, an additional transistor, and a transformer.

In this embodiment, the matching circuits or power combining stages are formed on a semiconductor integrated circuit.

A high-frequency amplifier having a cascode structure, to which the present invention is applied, includes a first amplification stage formed by a field effect transistor. The amplification stage is connected in a cascode structure in which one common source transistor is connected in parallel to a plurality of common gate transistors. The sources of the common gate transistors are connected to the drain of the common source transistor, and the drains of the common gate transistors are connected to power combining stages or matching circuits matching with different frequency regions and selectively switch on/off the gates of the common gate transistors.

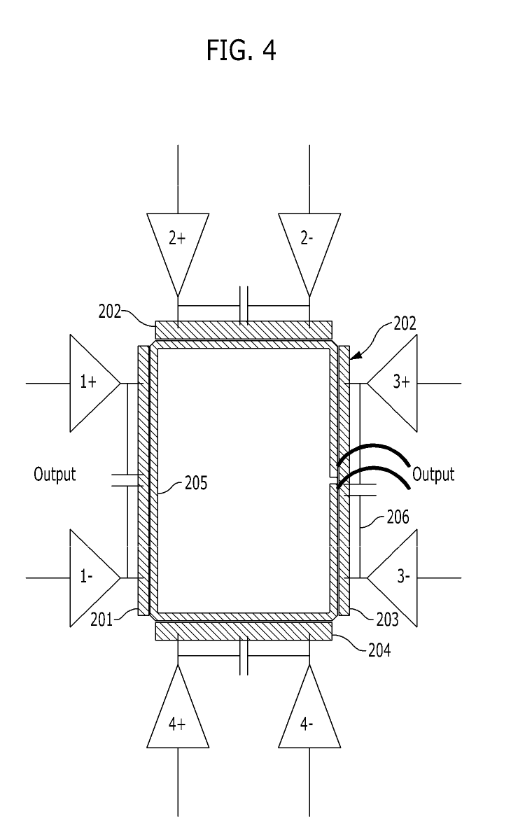

In this embodiment, the power combining stages include a high-frequency transformer which is configured by using a high-frequency transmission line as will be described below with reference to FIG. 4.

In accordance with the embodiment of the present invention, the output stage is connected to different matching circuits or power combining stages depending on the operation frequencies, and the transistors connected in parallel to different matching circuits or power combining stages are selectively switched on/off and selected. Therefore, the multi-band power amplifier in accordance with embodiment of the present invention may perform high power and high efficiency amplification in a plurality of frequency bands, while increasing the utilization of the circuit configuration without increasing the circuit size.

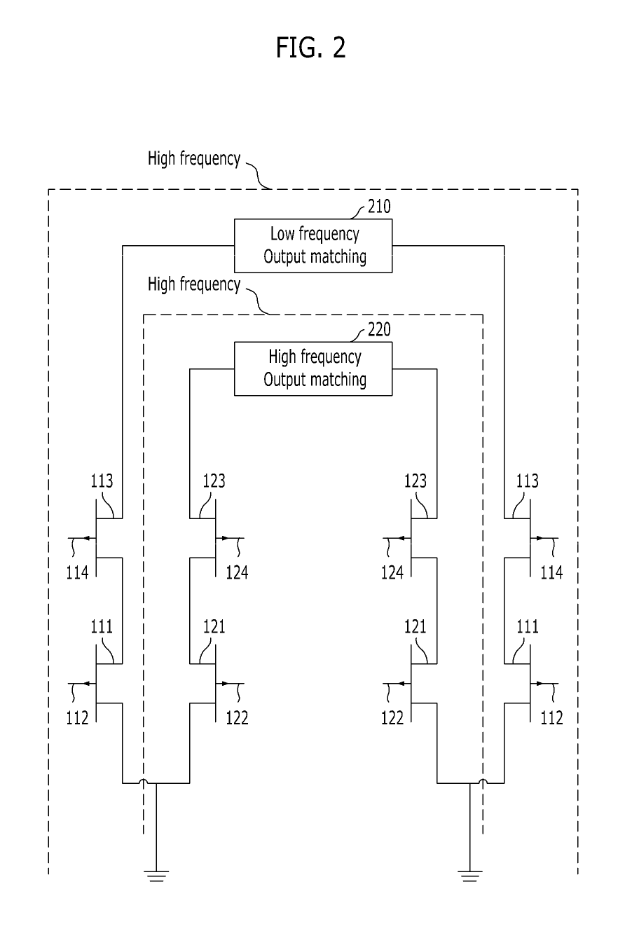

FIG. 2 is a diagram illustrating a combination form of a high-frequency amplifier and a high-frequency transformer of a multi-band power amplifier with a high-frequency transformer operating in two frequency bands, in accordance with an embodiment of the present invention. FIG. 2 illustrates a cascode structure of a field effect transistor which is used in the configuration of the amplifier circuit in accordance with the embodiment of the present invention. FIG. 2 illustrates a high-frequency amplifier having a differential structure.

Referring to FIG. 2, the high-frequency amplifier having a cascode structure includes common gate transistors 113 and 123 and common source transistors 111 and 121. The sources of the common gate transistors 113 and 123 are connected to the drains of the common source transistors 111 and 121.

The magnitude of voltages applied to the drains connected to output stages 210 and 220 in the power amplifier may cause degradation through breakdown. The structure of FIG. 2 prevents the degradation such that a stable operation may be accomplished.

In such a structure, the common gate transistors 113 and 123 and the common source transistors 111 and 121 are necessarily used to amplify input signals. During the operation, specific bias voltages 114 and 124 are applied to the common gate transistors 113 and 123, and the input signals to be amplified are applied through the gates 112 and 122 of the common source transistors 112 and 122.

Therefore, a current path is formed to perform the amplification in a state in which the two stages, that is, the common gate transistors and the common source transistors are all turned. The drains of the common gate transistors 113 and 123 are connected to the output stages 210 and 220 of the amplifier, and the output stages 210 and 220 are connected to matching circuits or power combining stages.

The structure of the high-frequency amplifier in accordance with the embodiment of the present invention is characterized in that one common gate transistor 113 or 123 is connected in parallel to additional common gate transistor 113 or 123 and the output stage 210 or 220, and the common gate transistors 113 and 123 are selectively switched on/off depending on the operation frequency band. For convenience of description, FIG. 2 illustrates the low-frequency output stage 210 and the high-frequency output stage 220 as the output stages of two different frequency bands.

Meanwhile, the gates, sources, and drains of the common source transistors 111 and 121 and the common gate transistors 113 and 123 and the output stages may be connected to inductors, resistors, capacitors, transmission lines, additional transistors, and transformers, in order to accomplish optimal matching.

As described above, the multi-band power amplifier in accordance with embodiment of the present invention may amplify a high frequency at high power and high efficiency in a plurality of frequency bands, while increasing the utilization of the circuit configuration without increasing the circuit size.

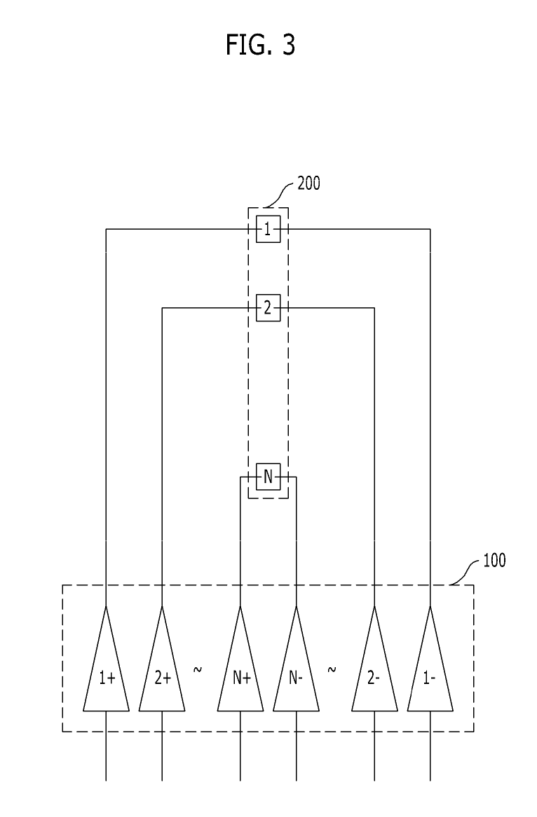

FIG. 3 is a diagram illustrating a combination of high-frequency transformers and input signals amplified by a plurality of amplifiers in a multi-band power amplifier using the plurality of high-frequency amplifiers operating in different frequency bands in accordance with another embodiment of the present invention. Although not illustrated in detail, the plurality of amplifiers 100 have a cascode structure in which common gate transistors are connected in parallel to the drains of common source transistors, as in FIG. 2.

The output stages of the common gate transistors are connected to power coupling stages 200 or matching circuits which are matched with different operation frequencies, and gate bias voltages of the common gate transistors are selectively switched on/off depending on the frequencies of signals inputted to the gates of the common source transistors.

Through such a configuration, two amplification paths of the common source transistors and the common gate transistors are selected depending on the setting of the gate bias voltages of the common gate transistors, and the amplification of the signals applied to the gates of the common source transistors is performed.

As illustrated in FIG. 3, the plurality of high-frequency amplifiers configured to amplify signals for a plurality of different operation frequencies, respectively, are implemented as differential pairs, and the signal amplified by each differential pair is connected to the matching circuit connected to the output stage thereof. Therefore, the multi-band power amplifier in accordance with embodiment of the present invention may amplify a high frequency at high power and high efficiency in a plurality of frequency bands, while increasing the utilization of the circuit configuration without increasing the circuit size.

FIG. 4 is a diagram illustrating a combination form of a high-frequency amplifier and a high-frequency transformer of a multi-band power amplifier in accordance with the embodiment of the present invention. The multi-band power amplifier in accordance with the embodiment of the present invention may operate as a perfect multi-band power amplifier in a plurality of frequency bands without a specific change of output matching.

Referring to FIG. 4, high-frequency amplifiers 1 to 4 configured to amplify different operation frequencies are connected to a plurality of primary-side transmission lines 201 to 204 formed in a high-frequency transformer 200, respectively. Signals applied to the primary-side transmission lines 201 to 204 are magnetically coupled to a secondary-side transmission line 205 which is formed in correspondence to the primary-side transmission lines, and transferred with a constant transfer coefficient so as to be outputted to the outside through output stages.

The thicknesses and lengths of the primary-side and secondary-side transmission lines in the above-described high-frequency transformer 200 may be adjusted to satisfy an optical matching condition in correspondence to each of different operation frequencies.

Meanwhile, the structure of the high-frequency transformer 200 illustrated in FIG. 4 may be changed, or a control capacitor 206 may be used to optimize the characteristics of the high-frequency transformer 200 to a desired frequency band.

At this time, the control capacitor 206 used to optimize the characteristics of the high-frequency transformer 200 to a desired frequency band may be implemented with a varactor and a switching capacitor using a plurality of transistors.

In accordance with the embodiments of the present invention, the high-frequency transformer is used in the high-frequency amplifier used in a wireless communication system. Therefore, it is possible to increase the utilization of the circuit configuration without increasing the circuit size of the high-frequency amplifier.

Furthermore, the embodiments of the present invention may provide a high-frequency amplifier which may be used in a plurality of frequency bands while increasing the utilization of the circuit configuration.

Furthermore, since a plurality of frequency bands may be implemented through a single transmission stage, a wireless transmission structure may support multi-band operations.

Furthermore, the high-frequency transformer may be used to increase the utilization of the circuit configuration of the high-frequency amplifier. Therefore, it is possible to reduce the manufacturing cost.

While the present invention has been described with respect to the specific embodiments, it will be apparent to those skilled in the art that various changes and modifications may be made without departing from the spirit and scope of the invention as defined in the following claims.

What is claimed is:

1. A multi-band power amplifier in a wireless communication system, comprising:
a plurality of matching circuits connected in parallel to an output stage of the power amplifier and corresponding to a plurality of different operation frequencies, respectively; and
a plurality of high-frequency amplifiers connected to the plurality of matching circuits, respectively,
wherein the plurality of high-frequency amplifiers are selectively operated depending on the operation frequencies.

2. The multi-band power amplifier of claim 1, wherein each of the high-frequency amplifiers comprises a plurality of stages.

3. The multi-band power amplifier of claim 1, wherein each of the matching circuits comprises a high-frequency transformer.

4. The multi-band power amplifier of claim 3, wherein the high-frequency transformer is matched by adjusting any one of the thickness and the length of a transmission line in correspondence to each of the operation frequencies.

5. The multi-band power amplifier of claim 3, wherein the high-frequency transformer uses a capacitor corresponding to each of the different operation frequencies.

6. The multi-band power amplifier of claim 5, wherein the capacitor is configured by using any one of a transistor switch and a varactor.

7. The multi-band power amplifier of claim 1, wherein each of the high-frequency amplifiers comprises a common source transistor and a common gate transistor which are connected in a cascode structure.

8. The multi-band power amplifier of claim 7, wherein the common source transistor and the common gate transistor have one terminal connected to at least any one of an inductor, a resistor, a capacitor, a transmission line, an additional transistor, and a transformer.

9. A multi-band power amplifier in a wireless communication system, comprising:
a plurality of high-frequency amplifiers having a cascode structure in which a plurality of common gate transistors have a source connected in parallel to a drain of one common source transistor; and
a plurality of matching circuits matched with different frequency regions and connected to drains of the common gate transistors, respectively,
wherein the gates of the common gate transistors are selectively switched on/off to selectively operate the plurality of high-frequency amplifiers depending on operation frequencies.

10. A multi-band power amplifier with a high-frequency amplifier, comprising:
a power amplification unit comprising:
a plurality of common source transistors connected in parallel to a ground terminal; and
a plurality of high-frequency amplifiers having a plurality of common gate transistors connected to the respective common source transistors in a cascode structure and configured to selectively amplify power of input signals each having a specific frequency; and
a high-frequency transformer comprising:
a plurality of primary-side transmission lines connected to the respective high-frequency amplifiers of the power amplification unit; and
a secondary-side transmission line magnetically coupled to signals applied to the respective primary-side transmission lines,
wherein the high-frequency transformer matches the plurality of signals having different frequencies, which are applied from the power amplification unit, and outputs the signals to an output stage.
